(19) United States
(12) Patent Application Publication
(10) Pub. No.: US 2017/0003499 A1
(43) Pub. Date: Jan. 5, 2017

(54) SILANE MODIFIED FLUID FOR MEMS STICTION REDUCTION

(71) Applicant: Pixtronix, Inc., San Diego, CA (US)

(72) Inventors: Ji Ma, Acton, MA (US); Xianhe Wei, Somerville, MA (US); Eugene Fike, III, Amesbury, MA (US); Tyler Dunn, North Reading, MA (US)

(21) Appl. No.: 14/790,633

(22) Filed: Jul. 2, 2015

(51) Int. Cl. G02B 26/04; B81B 3/00; G09G 3/34; B81C 1/00

(52) U.S. Cl. CPC G02B 26/04; B81C 1/00952; B81B 3/0016; G09G 3/3433

(57) ABSTRACT

This disclosure provides devices and methods of reducing stiction during a fluid-filling process. A device can include two substrates with movable MEMS components on at least one of the substrates. The device can include a fluid between the two substrates and surrounding or at least partially surrounding the movable MEMS components, where the fluid can serve as a lubricant for the movable MEMS components. The fluid can be a liquid solution doped with a surface energy modifier, where the surface energy modifier includes a nonpolar functional group R. In some implementations, the nonpolar functional group R can be selected from the group consisting of: alkyl, aryl and naphthenic.

### TECHNICAL FIELD

This disclosure relates to MEMS devices filled with fluid, and more particularly to MEMS devices with fluids doped with a surface energy modifier to reduce the effects of stiction during a fluid-filling process.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

Some MEMS-based devices are MEMS-based display devices that include a plurality of movable MEMS components disposed on a substrate and arranged in an array. An example of a movable MEMS component can include a shutter, where the shutter can function to modulate the passage of light through the MEMS-based display device. In some implementations, the MEMS-based device can be filled with a fluid that can serve as a lubricant for the movable MEMS components. In some implementations, the fluid also can serve to provide certain optical and electrical properties for the MEMS-based device. However, the movable MEMS component, such as the shutter, may be vulnerable to stiction during the fluid-filling process, where the movable MEMS component can adhere and become “stuck” to another surface in the MEMS-based device.

### SUMMARY

The systems, methods and devices of this disclosure each have several innovative aspects, no single one of which is solely responsible for the desirable attributes disclosed herein.

One innovative aspect of the subject matter described in this disclosure can be implemented in a device. The device includes a first substrate, a second substrate opposite the first substrate, a plurality of movable MEMS components over the second substrate, a fluid between the first substrate and the second substrate and surrounding the movable MEMS components and a seal for bonding the first substrate and the second substrate and enclosing the fluid in the device, where the fluid includes a surface energy modifier including a nonpolar functional group R.

In some implementations, the nonpolar functional group R is selected from the group consisting of: alkyl, aryl, and naphthenic. In some implementations, the surface energy modifier includes a silicon atom, the nonpolar functional group R and a hydrolysable group R′, where the hydrolysable group R′ is selected from the group consisting of: alkoxy, acyloxy, amine and chlorine. In some implementations, the surface energy modifier is between about 0.5 volume percent and about 5.0 volume percent of the fluid. In some implementations, the first substrate includes an aperture plate and the second substrate includes a MEMS substrate, where an inner surface of the MEMS substrate has a higher surface energy than an inner surface of the aperture plate. In some implementations, the surface energy modifier is capable of reducing the surface energy of the MEMS substrate. In some implementations, the fluid includes an organic solvent. The surface energy modifier is dissolved in the organic solvent. In some implementations, each of the movable MEMS components includes a shutter in a shutter-based MEMS light modulator.

Another innovative aspect of the subject matter described in this disclosure can be implemented in a device. The device includes a first substrate, a second substrate opposite the first substrate, a plurality of movable MEMS components over the second substrate, where a surface energy of a surface of the movable MEMS components is greater than a surface energy of the first substrate, and a fluid between the first substrate and the second substrate and surrounding the movable MEMS components. The fluid includes a solvent and means for modifying a surface energy of the surface of the movable MEMS components, where the surface energy modifying means includes a nonpolar functional group R. The device further includes a seal for bonding the first substrate and the second substrate and enclosing the fluid in the device.

In some implementations, the nonpolar functional group R is selected from the group consisting of: alkyl, aryl, and naphthenic. In some implementations, the surface energy modifying means includes a silicon atom, the nonpolar functional group R and a hydrolysable group R′, where the hydrolysable group R′ is selected from the group consisting of: alkoxy, acyloxy, amine and chlorine. In some implementations, the surface energy modifying means is between about 0.5 volume percent and about 5.0 volume percent of the fluid.

Another innovative aspect of the subject matter described in this disclosure can be implemented in a method. The method includes providing a first substrate, providing a second substrate that is opposite the first substrate, forming a plurality of movable MEMS components over the second substrate, bonding the first substrate to the second substrate and filling the device with a fluid between the first substrate and the second substrate, where the fluid surrounds the movable MEMS components and includes a surface energy modifier, the surface energy modifier including a nonpolar functional group R.

In some implementations, the nonpolar functional group R is selected from the group consisting of: alkyl, aryl, and naphthenic. In some implementations, the surface energy modifier is between about 0.5 volume percent and about 5.0 volume percent of the fluid. In some implementations, the surface energy modifier in the fluid prevents stiction between the movable MEMS components and the first substrate or the second substrate during filling. In some implementations, the method further includes annealing the device to a temperature greater than about 100° C.

Details of one or more implementations of the subject matter described in this disclosure are set forth in the accompanying drawings and the description below. Other features, aspects and advantages will become apparent from the description, the drawings and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS)-based display apparatus.

FIG. 1B shows a block diagram of an example host device.

FIGS. 2A and 2B show views of an example dual actuator shutter assembly.

FIG. 3 shows a perspective view of an example shutter assembly according to some implementations.

FIG. 4 shows a cross-sectional schematic view of an example MEMS device filled with a fluid.

FIG. 5A shows an image of an array of MEMS elements in an example MEMS device illustrating the effects of stiction after the MEMS device is filled with fluid.

FIG. 5B shows an image of an array of MEMS elements in an example MEMS device illustrating the effects of stiction reduction by a surface energy modifier after the MEMS device is filled with fluid.

FIG. 6A shows a cross-sectional schematic view illustrating an example MEMS surface with surface hydroxyls.

FIG. 6B shows a cross-sectional schematic view illustrating an example MEMS surface with a modified surface interacting with a fluid.

FIG. 6C shows a cross-sectional schematic view illustrating an example MEMS surface with a modified surface following an annealing process.

FIG. 7 shows a flow diagram illustrating an example process for manufacturing a device.

FIGS. 8A and 8B show system block diagrams of an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that is capable of displaying an image, whether in motion (such as video) or stationary (such as still images), and whether textual, graphical or pictorial. The concepts and examples provided in this disclosure may be applicable to a variety of displays, such as liquid crystal displays (LCDs), organic light-emitting diode (OLED) displays, field emission displays, and electromechanical systems (EMS) and microelectromechanical (MEMS)-based displays, in addition to displays incorporating features from one or more display technologies.

The described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, wearable devices, clocks, calculators, television monitors, flat panel displays, electronic reading devices (such as e-readers), computer monitors, auto displays (such as odometer and speedometer displays), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, in addition to non-EMS applications), aesthetic structures (such as display of images on a piece of jewelry or clothing) and a variety of EMS devices.

The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

A device can be filled with a fluid that serves to lubricate movable MEMS components in the device. The fluid can be doped with a surface energy modifier to reduce the effects of stiction during the fluid-filling process. The surface energy modifier can include nonpolar functional group R. The surface energy modifier can be capable of reducing the surface energy of a surface in the device, such as the surface of the movable MEMS components. In some implementations, the nonpolar functional group R is selected from the group consisting of: alkyl, aryl and naphthenic. In some implementations, the surface energy modifier includes a silicon atom, the nonpolar functional group R and a hydrolysable group R′, where the hydrolysable group R′ is selected from the group consisting of: alkoxy, acyloxy, amine and chlorine. In some implementations, the surface energy modifier is between about 0.5 volume percent and about 5.0 volume percent of the fluid. For example, the volume percent ratio of the fluid to surface energy modifier can be 20:1, 50:1, 100:1, or greater than 100:1.

Particular implementations of the subject matter described in this disclosure can be implemented to realize one or more of the following potential advantages. A surface energy modifier in the fluid of a device alleviates stiction that can occur between surfaces in the device during the fluid-filling process. This can result in fewer movable MEMS components that are “stuck,” which can otherwise lead to reduced device performance and even device failure. The fluid with the surface energy modifier not only can improve device performance, but also can reduce cost and delays that would be associated with releasing “stuck” MEMS components. Also, rather than depositing a thin film or self-assembled monolayer (SAM) coating to obtain a low energy surface, the surface energy modifier can reduce the surface energy on movable MEMS components and function similar with a low energy surface coating. Depositing thin films and SAM coatings can involve additional manufacturing steps and equipment, which can make the deposition of such thin films or coatings cumbersome, time-consuming and costly. However, the fluid with a surface energy modifier can functionally obtain a low energy surface coating without the costs associated with depositing thin films and SAM coatings. For example, the process of preparing the surface energy modifier and dissolving the surface energy modifier in the fluid can be relatively simple compared to the process of preparing and depositing thin films and SAM coatings.

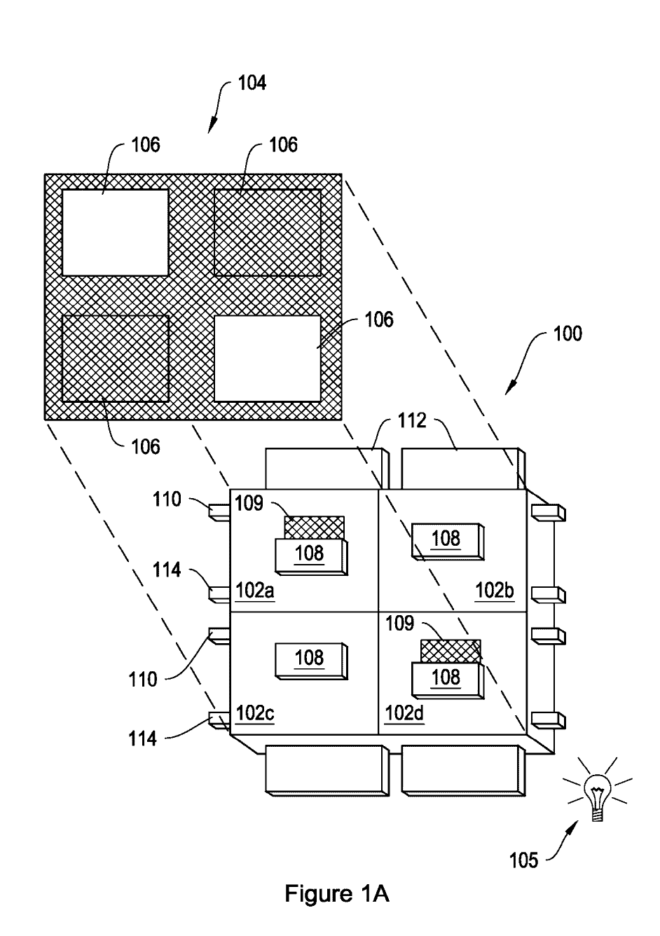

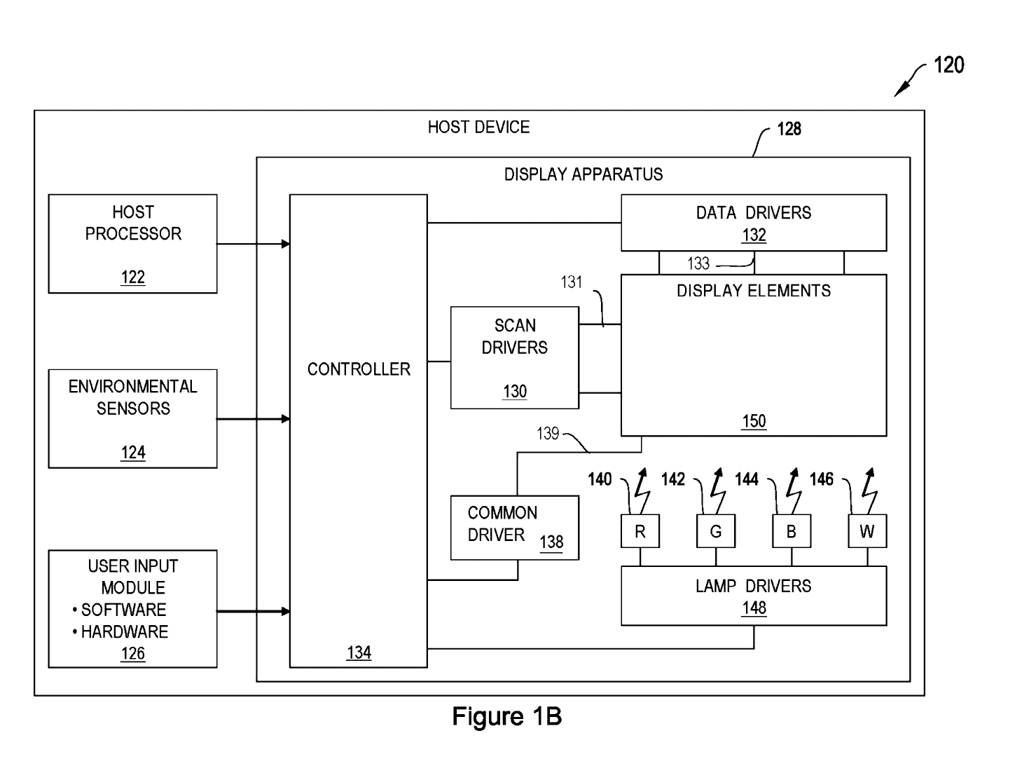

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the image can be seen by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent substrates to facilitate a sandwich assembly arrangement where one substrate, containing the light modulators, is positioned over the backlight. In some implementations, the transparent substrate can be a glass substrate (sometimes referred to as a glass plate or panel), or a plastic substrate. The glass substrate may be or include, for example, a borosilicate glass, wine glass, fused silica, a soda lime glass, quartz, artificial quartz, Pyrex, or other suitable glass material.

Each light modulator 102 can include a shutter 108 and an aperture 109. To illuminate a pixel 106 in the image 104, the shutter 108 is positioned such that it allows light to pass through the aperture 109. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix coupled to the substrate and to the light modulators for controlling the movement of the shutters. The control matrix includes a series of electrical interconnects (such as interconnects 110, 112 and 114), including at least one write-enable interconnect 110 (also referred to as a scan line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate drive voltages, which are typically higher in magnitude than the data voltages, to the light modulators 102. The application of these drive voltages results in the electrostatic driven movement of the shutters 108.

The control matrix also may include, without limitation, circuitry, such as a transistor and a capacitor associated with each shutter assembly. In some implementations, the gate of each transistor can be electrically connected to a scan line interconnect. In some implementations, the source of each transistor can be electrically connected to a corresponding data interconnect. In some implementations, the drain of each transistor may be electrically connected in parallel to an electrode of a corresponding capacitor and to an electrode of a corresponding actuator. In some implementations, the other electrode of the capacitor and the actuator associated with each shutter assembly may be connected to a common or ground potential. In some other implementations, the transistor can be replaced with a semiconducting diode, or a metal-insulator-metal switching element.

FIG. 1B shows a block diagram of an example host device 120 (i.e., cell phone, smart phone, PDA, MP3 player, tablet, e-reader, netbook, notebook, watch, wearable device, laptop, television, or other electronic device). The host device 120 includes a display apparatus 128 (such as the display apparatus 100 shown in FIG. 1A), a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148 and an array of display elements 150, such as the light modulators 102 shown in FIG. 1A. The scan drivers 130 apply write enabling voltages to scan line interconnects 131. The data drivers 132 apply data voltages to the data interconnects 133.

In some implementations of the display apparatus, the data drivers 132 are capable of providing analog data voltages to the array of display elements 150, especially where the luminance level of the image is to be derived in analog fashion. In analog operation, the display elements are designed such that when a range of intermediate voltages is applied through the data interconnects 133, there results a range of intermediate illumination states or luminance levels in the resulting image. In some other implementations, the data drivers 132 are capable of applying a reduced set, such as 2, 3 or 4, of digital voltage levels to the data interconnects 133. In implementations in which the display elements are shutter-based light modulators, such as the light modulators 102 shown in FIG. 1A, these voltage levels are designed to set, in digital fashion, an open state, a closed state, or other discrete state to each of the shutters 108. In some implementations, the drivers are capable of switching between analog and digital modes.

The scan drivers 130 and the data drivers 132 are connected to a digital controller circuit 134 (also referred to as the controller 134). The controller 134 sends data to the data drivers 132 in a mostly serial fashion, organized in sequences, which in some implementations may be predetermined, grouped by rows and by image frames. The data drivers 132 can include series-to-parallel data converters, level-shifting, and for some applications digital-to-analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 139. In some other implementations, the common drivers 138, following commands from the controller 134, issue voltage pulses or signals to the array of display elements 150, for instance global actuation pulses which are capable of driving and/or initiating simultaneous actuation of all display elements in multiple rows and columns of the array.

Each of the drivers (such as scan drivers 130, data drivers 132 and common drivers 138) for different display functions can be time-synchronized by the controller 134. Timing commands from the controller 134 coordinate the illumination of red, green, blue and white lamps (140, 142, 144 and 146 respectively) via lamp drivers 148, the write-enabling and sequencing of specific rows within the array of display elements 150, the output of voltages from the data drivers 132, and the output of voltages that provide for display element actuation. In some implementations, the lamps are light emitting diodes (LEDs).

The controller 134 determines the sequencing or addressing scheme by which each of the display elements can be re-set to the illumination levels appropriate to a new image 104. New images 104 can be set at periodic intervals. For instance, for video displays, color images or frames of video are refreshed at frequencies ranging from 10 to 300 Hertz (Hz). In some implementations, the setting of an image frame to the array of display elements 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human visual system (HVS) will average the alternating frame images into the perception of an image having a broad and continuous range of colors. In some other implementations, the lamps can employ primary colors other than red, green, blue and white. In some implementations, fewer than four, or more than four lamps with primary colors can be employed in the display apparatus 128.

In some implementations, where the display apparatus 128 is designed for the digital switching of shutters, such as the shutters 108 shown in FIG. 1A, between open and closed states, the controller 134 forms an image by the method of time division gray scale. In some other implementations, the display apparatus 128 can provide gray scale through the use of multiple display elements per pixel.

In some implementations, the data for an image state is loaded by the controller 134 to the array of display elements 150 by a sequential addressing of individual rows, also referred to as scan lines. For each row or scan line in the sequence, the scan driver 130 applies a write-enable voltage to the write enable interconnect 131 for that row of the array of display elements 150, and subsequently the data driver 132 supplies data voltages, corresponding to desired shutter states, for each column in the selected row of the array. This addressing process can repeat until data has been loaded for all rows in the array of display elements 150. In some implementations, the sequence of selected rows for data loading is linear, proceeding from top to bottom in the array of display elements 150. In some other implementations, the sequence of selected rows is pseudo-randomized, in order to mitigate potential visual artifacts. And in some other implementations, the sequencing is organized by blocks, where, for a block, the data for a certain fraction of the image is loaded to the array of display elements 150. For example, the sequence can be implemented to address every fifth row of the array of the display elements 150 in sequence.

In some implementations, the addressing process for loading image data to the array of display elements 150 is separated in time from the process of actuating the display elements. In such an implementation, the array of display elements 150 may include data memory elements for each display element, and the control matrix may include a global actuation interconnect for carrying trigger signals, from the common driver 138, to initiate simultaneous actuation of the display elements according to data stored in the memory elements.

In some implementations, the array of display elements 150 and the control matrix that controls the display elements may be arranged in configurations other than rectangular rows and columns. For example, the display elements can be arranged in hexagonal arrays or curvilinear rows and columns.

The host processor 122 generally controls the operations of the host device 120. For example, the host processor 122 may be a general or special purpose processor for controlling a portable electronic device. With respect to the display apparatus 128, included within the host device 120, the host processor 122 outputs image data as well as additional data about the host device 120. Such information may include data from environmental sensors 124, such as ambient light or temperature; information about the host device 120, including, for example, an operating mode of the host or the amount of power remaining in the host device's power source; information about the content of the image data; information about the type of image data; and/or instructions for the display apparatus 128 for use in selecting an imaging mode.

In some implementations, the user input module 126 enables the conveyance of personal preferences of a user to the controller 134, either directly, or via the host processor 122. In some implementations, the user input module 126 is controlled by software in which a user inputs personal preferences, for example, color, contrast, power, brightness, content, and other display settings and parameters preferences. In some other implementations, the user input module 126 is controlled by hardware in which a user inputs personal preferences. In some implementations, the user may input these preferences via voice commands, one or more buttons, switches or dials, or with touch-capability. The plurality of data inputs to the controller 134 direct the controller to provide data to the various drivers 130, 132, 138 and 148 which correspond to optimal imaging characteristics.

The environmental sensor module 124 also can be included as part of the host device 120. The environmental sensor module 124 can be capable of receiving data about the ambient environment, such as temperature and or ambient lighting conditions. The sensor module 124 can be programmed, for example, to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

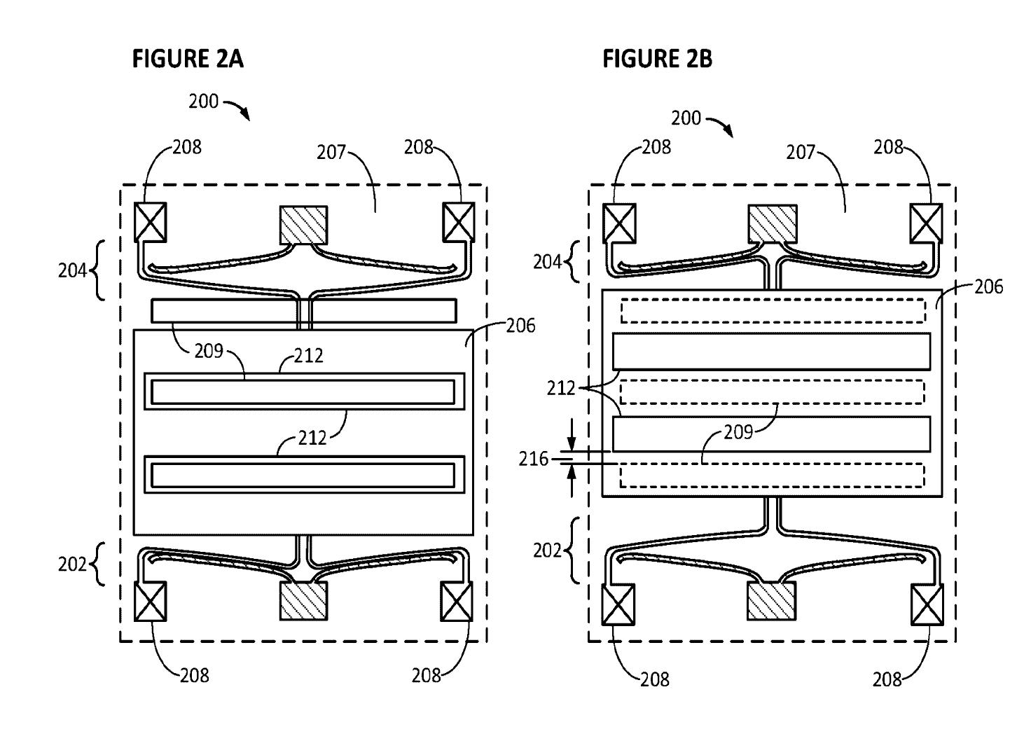

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Each of the actuators 202 and 204 can be implemented as compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. Having the actuators 202 and 204 attach to opposing ends of the shutter 206 along its axis of movement reduces out of plane motion of the shutter 206 and confines the motion substantially to a plane parallel to the substrate (not depicted).

In the depicted implementation, the shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B, the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In some implementations, in which circular, elliptical, oval, or other curved apertures are formed in the aperture layer 207, each aperture may have a single edge. In some other implementations, the apertures need not be separated or disjointed in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through the apertures 212 and 209 in the open state, the width or size of the shutter apertures 212 can be designed to be larger than a corresponding width or size of apertures 209 in the aperture layer 207. In order to effectively block light from escaping in the closed state, the light blocking portions of the shutter 206 can be designed to overlap the edges of the apertures 209. FIG. 2B shows an overlap 216, which in some implementations can be predefined, between the edge of light blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators, there exists a range of voltages below the actuation voltage, which if applied while that actuator is in the closed state (with the shutter being either open or closed), will hold the actuator closed and the shutter in position, even after a drive voltage is applied to the opposing actuator. The minimum voltage needed to maintain a shutter's position against such an opposing force is referred to as a maintenance voltage Vₘ.

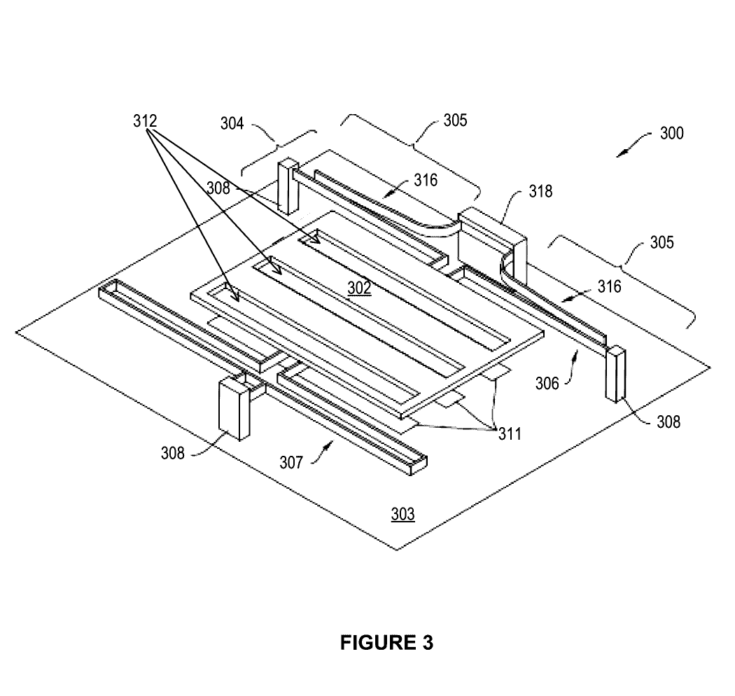

FIG. 3 shows a perspective view of an example shutter assembly according to some implementations. The shutter assembly 300 can be similar to the shutter assembly 200 shown and described with reference to FIGS. 2A and 2B. However, a shutter 302 in the shutter assembly 300 includes at least three apertures 312 through which light can pass. In some implementations, the shutter assembly 300 can be an example of a single-actuator shutter assembly having a single actuator.

The shutter assembly 300 can be incorporated in MEMS-based devices. The shutter assembly 300 can include a shutter 302 coupled to an actuator 304. The actuator 304 can be formed from two separate compliant beam actuators 305 (the “actuators 305”). The shutter 306 couples to one side of the actuators 305. The actuators 305 move the shutter 302 transversely over a surface 303 in a plane of motion which is substantially parallel to the surface 303. The opposite side of the shutter 302 couples to a spring 307 which provides a restoring force opposing the forces exerted by the actuator 304.

Each actuator 305 includes a compliant load beam 306 connecting the shutter 302 to a load anchor 308. The load anchors 308 along with the compliant load beams 306 serve as mechanical supports, keeping the shutter 302 suspended proximate the surface 303. The surface 303 includes one or more aperture holes 311 for admitting the passage of light. The load anchors 308 physically connect the compliant load beams 306 and the shutter 302 to the surface 303 and electrically connect the load beams 306 to a bias voltage, in some instances, ground.

If the substrate is opaque, such as silicon, then aperture holes 311 are formed in the substrate by etching an array of holes through the substrate. If the substrate is transparent, such as glass or plastic, then the aperture holes 311 are formed in a layer of light-blocking material deposited on the substrate. The aperture holes 311 can be generally circular, elliptical, polygonal, serpentine, or irregular in shape.

Each actuator 305 also includes a compliant drive beam 316 positioned adjacent to each load beam 306. The drive beams 316 couple at one end to a drive beam anchor 318 shared between the drive beams 316. The other end of each drive beam 316 is free to move. Each drive beam 316 is curved such that it is closest to the load beam 306 near the free end of the drive beam 316 and the anchored end of the load beam 306.

In operation, a display apparatus incorporating the light modulator 300 applies an electric potential to the drive beam 316 via a drive beam anchor 318. A second electric potential may be applied to the load beams 306. The resulting potential difference between the drive beams 316 and the load beams 306 pulls the free ends of the drive beams 316 towards the anchored ends of the load beams 306, and pulls the shutter ends of the load beams 306 toward the anchored ends of the drive beams 316, thereby driving the shutter 302 transversely toward the drive anchor 318. The compliant members 306 act as springs, such that when the voltage across the beams 306 and 316 potential is removed, the load beams 306 push the shutter 302 back into its initial position, releasing the stress stored in the load beams 306.

A light modulator, such as the light modulator 300, incorporates a passive restoring force, such as a spring, for returning a shutter to its rest position after voltages have been removed. Other shutter assemblies can incorporate a dual set of “open” and “closed” actuators and a separate set of “open” and “closed” electrodes for moving the shutter into either an open or a closed state.

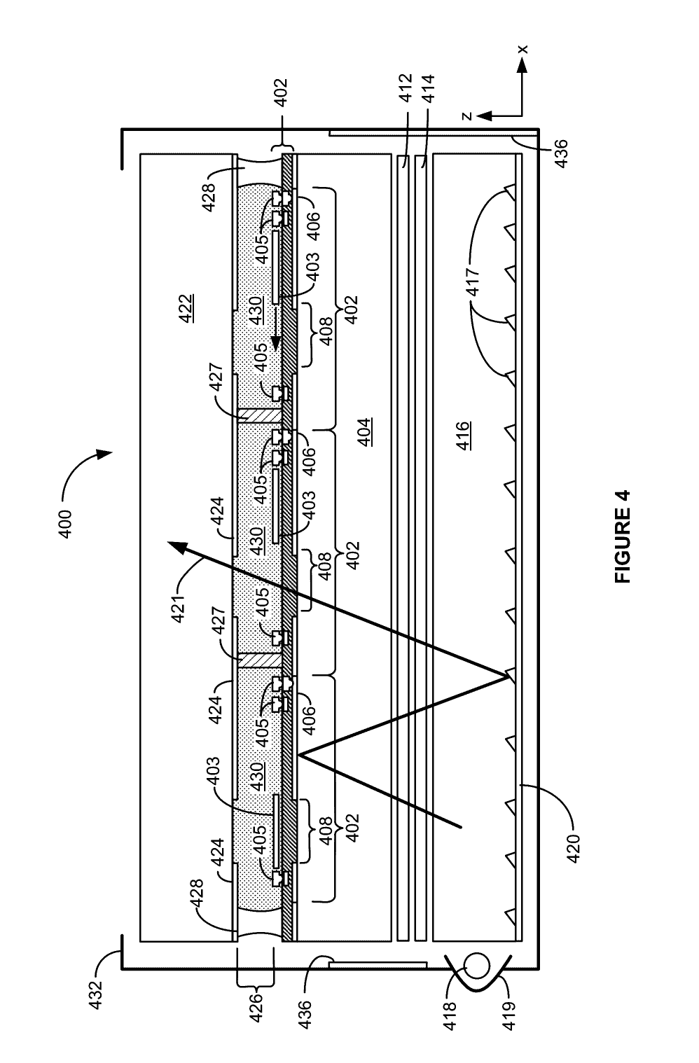

FIG. 4 shows a cross-sectional schematic view of an example MEMS device filled with a fluid. The MEMS device 400 can include a first substrate 422 and a second substrate 404 opposite the first substrate 422. The first substrate 422 can be referred to as a cover plate or an aperture plate. In some implementations, the first substrate 422 can serve as a transparent cover. The second substrate 404 may provide a surface upon which various display elements, movable MEMS components, thin film transistors (TFTs) and other device components may be built, placed, positioned or formed upon. The second substrate may be referred to as a back plate or MEMS substrate. In some implementations, the first substrate 422 and the second substrate 404 may be made of the same material. For example, the first substrate 422 and the second substrate 404 can each include plastic, glass or other suitable transparent material. In some implementations, the second substrate 404 can include a non-transparent or semi-transparent material, such as silicon.

The MEMS device 400 can include a plurality of MEMS elements or MEMS display elements 402. The plurality of MEMS display elements 402 may be arranged as an array of display elements, which can represent pixels in a display. Hundreds, thousands or millions of pixels may be arranged in hundreds or thousands of rows and hundreds or thousands of columns. Each of the MEMS display elements 402 may be driven by one or more TFTs. In some implementations, the MEMS display elements 402 can include shutter-based light modulators (shutter assemblies). Examples of shutter-based light modulators are discussed with reference to light modulators 102 in FIG. 1A, display elements 150 in FIG. 1B, dual actuator shutter assemblies 200 in FIGS. 2A and 2B and shutter assemblies 300 in FIG. 3.

The plurality of MEMS elements 402 can include a plurality of movable MEMS components 403, where the movable MEMS components 403 can be positioned over the second substrate 404. Each of the movable MEMS components 403 may be configured to actuate in response to an applied voltage. In some implementations, the movable MEMS component 403 may be actuatable to open, closed and intermediate positions for each MEMS display element 402.

The MEMS device 400 can be filled or at least partially filled with a fluid 430. The fluid 430 can be contained between the first substrate 422 and the second substrate 404. The fluid 430 can surround the movable MEMS components 403 or at least partially surround the movable MEMS components 403 inside the MEMS device 400. The MEMS device 400 includes a liquid solution for the fluid 430, where the liquid solution wets or substantially wets the surfaces of the movable MEMS components 403. The liquid solution can serve as a lubricant for the movable MEMS components 403.

The fluid 430 can be enclosed in the MEMS device 400 between the two substrates 422 and 404 when the MEMS device 400 is sealed. The MEMS device 400 can include a seal 428 that seals in the fluid 430. The seal 428 can be disposed between the two substrates 422 and 404 so that the two substrates 422 and 404 may be bonded or attached to one another. In some implementations, the seal 428 may be provided along a perimeter of the MEMS device 400. Different types of seals may be applied to form the seal 428. In some implementations, the seal 428 can include a non-hermetic or semi-hermetic seal, such as an epoxy adhesive. In some implementations, the seal 428 can include a hermetic seal, such as a glass frit or solder. In some implementations, a gap 426 is defined between the two substrates 422 and 404, where the gap 426 is maintained by mechanical supports or spacers 427 as well as by the seal 428.

In FIG. 4, the MEMS device 400 can be a MEMS display device incorporating a plurality of shutter-based light modulators 402. Each shutter-based light modulator 402 can include a shutter 403 and an anchor 405. Not shown are the compliant beam actuators which, when connected between the anchors 405 and the shutters 403, help to suspend the shutters 403 a short distance above the surface. The shutter-based light modulators 402 are disposed on the second substrate 404, where such a substrate can be made of plastic, glass or any other suitable substrate material. A rear-facing reflective layer, such as reflective film 406, disposed on the second substrate 404 defines a plurality of surface apertures 408 located beneath the shutters 403 when the shutters 403 are in a closed position. The closed position of the shutter 403 can represent the position of the shutter 403 configured to substantially block the passage of light through the surface apertures 408. The reflective film 406 reflects light not passing through the surface apertures 408 back towards the rear of the MEMS display device 400. The reflective film 406 can be a fine-grained metal film without inclusions formed in thin film fashion by a number of vapor deposition techniques, including sputtering, evaporation, ion plating, laser ablation or chemical vapor deposition (CVD). In some implementations, the rear-facing reflective film 406 can be formed from a mirror, such as a dielectric mirror. A dielectric mirror can be fabricated as a stack of dielectric thin films which alternate between materials of high and low refractive index. The vertical gap which separates the shutter 403 from the reflective film 406, within which the shutter 403 is free to move, is in the range of range of 0.5 microns to 10 microns. For example, the vertical gap can be 1 micron, 2 microns, 5 microns, or greater than 5 microns. The magnitude of the vertical gap can be less than the lateral overlap between the edge of the shutters 403 and the edge of the surface apertures 408 in the closed state.

In some implementations, the MEMS display device 400 can include an optional diffuser 412 and/or an optional brightness enhancing film 414 which separate the second substrate 404 from a planar light guide 416. The light guide 416 can include a transparent material. The light guide 416 can be illuminated by one or more light sources 418, forming a backlight. The light sources 418 can be, for example, and without limitation, incandescent lamps, fluorescent lamps, lasers or light-emitting diodes (LEDs). A reflector 419 can help direct light from the light source 418 towards the light guide 416. A front-facing reflective film 420 can be disposed behind the light guide 416, reflecting light towards the shutter-based light modulators 402. Light rays, such as light ray 421, from the light guide 416 that do not pass through one of the shutter-based light modulators 402 will be returned to the light guide 416 and reflected again from the front-facing reflective film 420. In this fashion, light that fails to leave the MEMS display device 400 to form an image on the first pass can be recycled and made available for transmission through other open apertures in the array of the shutter-based light modulators 402. Such light recycling has been shown to increase the illumination efficiency of a display.

The light guide 416 can include a set of geometric light redirectors or prisms 417 which redirect light from the light sources 418 towards the apertures 408 and hence, towards the front of the display. The light redirectors 417 can be molded into the plastic body of the light guide 416 with shapes that can be alternately triangular, trapezoidal or curved in cross-section. The density of the light redirectors 417 generally increases with distance from the light source 418.

In some implementations, the reflective film 406 can be made of a light absorbing material, and in some other implementations, the surfaces of the shutter 403 can be coated with either a light absorbing or a light reflecting material. In some other implementations, the reflective film 406 can be deposited directly on the surface of the light guide 416. In some implementations, the reflective film 406 need not be disposed on the same substrates as the shutters 403 and anchors 405.

In some implementations, the light sources 418 can include lamps of different colors, for example, the colors red, green and blue. A color image can be formed by sequentially illuminating images with lamps of different colors at a rate sufficient for the human brain to average the different colored images into a single multi-color image. The various color-specific images are formed using the array of shutter-based light modulators 402. In some other implementations, the light source 418 includes lamps having more than three different colors. For example, the light source 418 may have red (R), green (G), blue (B) and white (W) lamps, or red, green, blue and yellow (Y) lamps. In some other implementations, the light source 418 may include cyan (C), magenta (M), yellow and white lamps or red, green, blue and white lamps. In some other implementations, additional lamps may be included in the light source 418. For example, if using five colors, the light source 418 may include red, green, blue, cyan and yellow lamps. In some other implementations, the light source 418 may include white, orange (O), blue, purple (P) and green lamps or white, blue, yellow, red and cyan lamps. If using six colors, the light source 418 may include red, green, blue, cyan, magenta and yellow lamps or white, cyan, magenta, yellow, orange and green lamps.

A first substrate or cover plate 422 can form the front of the MEMS display device 400. The rear side of the cover plate 422 can be covered with a black matrix 424 to increase contrast. In some other implementations, the cover plate 422 includes color filters, for example, distinct red, green and blue filters corresponding to different ones of the shutter-based light modulators 402. The cover plate 422 can be supported a certain distance away from the shutter-based light modulators 402 forming a gap 426. The gap 426 can be maintained by mechanical supports or spacers 427 and/or by an adhesive seal 428 attaching the cover plate 422 to the second substrate 404.

The adhesive seal 428 can seal in the fluid 430. The fluid 430 can be engineered with viscosities below about 10 centipoise and with relative dielectric constant above about 2.0, and dielectric breakdown strengths above about 10⁴ V/cm. The fluid 430 also can serve as a lubricant, such as a lubricant for moving parts in the MEMS display device 400. In some implementations, the fluid 430 is a hydrophobic liquid with a high surface wetting capability. In some implementations, the fluid 430 has a refractive index that is either greater than or less than that of the second substrate 404.

MEMS display devices 400 can incorporate hundreds, thousands, or in some cases, millions of moving parts. In some implementations, every movement of a moving part provides opportunity for static friction to disable one or more of the moving parts. This movement can be facilitated by immersing all the moving parts in the fluid 430, and sealing the fluid within the gap 426 between the two substrates 422 and 404 using the adhesive seal 428. The fluid 430 is usually one with a low coefficient of friction, low viscosity and minimal degradation effects over the long term. When the MEMS display device 400 includes a liquid solution for the fluid 430, the liquid solution surrounds or at least partially surrounds the moving parts of the MEMS display device 400. In some implementations, in order to reduce the actuation voltages, the liquid can have a viscosity below about 70 centipoise. In some implementations, the liquid can have a viscosity below about 10 centipoise. Liquids with viscosities below 70 centipoise can include materials with low molecular weights: below 4000 grams/mole, or in some cases below 400 grams/mole. Fluids 430 that also may be suitable for such implementations include, without limitation, de-ionized water, methanol, ethanol and other alcohols, paraffins, olefins, ethers, silicone oils, fluorinated silicone oils or other natural or synthetic solvents or lubricants. Useful fluids can be polydimethylsiloxanes (PDMS), such as hexamethyldisiloxane and octamethyltrisiloxane or alkyl methyl siloxanes such as hexylpentamethyldisiloxane. Useful fluids can be alkanes, such as octane or decane. Useful fluids can be nitroalkanes, such as nitromethane. Useful fluids can be aromatic compounds, such as toluene or diethylbenzene. Useful fluids can be ketones, such as butanone or methyl isobutyl ketone. Useful fluids can be chlorocarbons, such as chlorobenzene. Useful fluids can be chlorofluorocarbons, such as dichlorofluoroethane or chlorotrifluoroethylene. Other fluids considered for these display assemblies include butyl acetate and dimethylformamide. Still other useful fluids for these displays include hydro fluoro ethers, perfluoropolyethers, hydro fluoro poly ethers, pentanol and butanol. Example suitable hydro fluoro ethers include ethyl nonafluorobutyl ether and 2-trifluoromethyl-3-ethoxydodecafluorohexane.

A sheet metal or molded plastic assembly bracket 432 can hold the first substrate 422, the second substrate 404, the light guide 416 and the other component parts together around the edges. The assembly bracket 432 can be fastened with screws or indent tabs to add rigidity to the MEMS display device 400. In some implementations, the light source 418 can be molded in place by an epoxy potting compound. Reflectors 436 can help return light escaping from the edges of the light guide 416 back into the light guide 416. Not depicted in FIG. 4 are electrical interconnects which provide control signals as well as power to the shutter-based light modulators 402 and the light sources 418.

As discussed earlier, the fluid 430 can serve as a lubricant for the moving mechanical parts of the MEMS device 400, such as the shutter 403 of shutter-based light modulators 402. As a lubricant, the chemistry of the fluid 430 can be selected to have low surface energy so as to minimize interactions with the moving mechanical parts. For example, the fluid 430 can include silicone oil or other organic solvent. In some implementations, the fluid 430 can provide certain optical and electrical properties to the MEMS device 400.

In some implementations, a surface of the first substrate 422 facing the fluid 430 can have a different surface energy than a surface of the second substrate 404 facing the fluid 430. For example, the surface energy of the first substrate 422 can be relatively low while the surface energy of the second substrate 404 can be relatively high. In some implementations, an inner surface of the first substrate 422 can include a metal oxide. In some implementations, an inner surface of the second substrate 404 can include at least one of silicon, a nitride (such as SiNx, AlN, etc.), an oxide (such as SiO₂, Al₂O₃, etc.), and a metal (such as Al, Ti, Au, Pt, etc.). The inner surface of the second substrate 404 can include a layer of at least one of the movable MEMS components 403, where the layer of the movable MEMS components 403 can interact with the fluid 430. In some implementations, each of the movable MEMS components 403 can include a shutter in a shutter-based MEMS light modulator.

During a process of filling the MEMS device 400 with the fluid 430, charge can build up in certain parts of the fluid 430. This can result due in part to the differences in surface energies of the first substrate 422, the fluid 430 and the second substrate 404. When the MEMS device 400 is filled with the fluid 430, charge can migrate off certain parts of the MEMS device 400 and into the fluid 430. Such charge migration also may result from a triboelectric effect due to friction between the movable MEMS components 403 and the fluid 430. For example, the friction can result from movement of shutters 403 between open and closed positions. The friction between charged surfaces, including friction between the fluid 430 having low surface energy and the layer of the movable MEMS components 403 having high surface energy, can cause charge to migrate and build up in certain parts of the fluid 430. In some implementations, charge migration unrelated to friction of charged surfaces can cause charge to build up.

When the fluid 430 is provided in the MEMS device 400 between the substrates 422 and 404, the movement of the fluid 430 across the inner surfaces of the substrates 422 and 404 can occur at different velocities. In some implementations, the velocity of the fluid 430 across the inner surface of the first substrate 422 can be faster than the velocity of the fluid 430 across the inner surface of the second substrate 404. The friction produced between the fluid 430 and the inner surface of the second substrate 404 can cause charge to migrate into the fluid 430 and towards the inner surface of the first substrate 422.

Regardless of the causes, charge buildup can produce undesirable effects in the operation of the MEMS device 400. In particular, the charge buildup can produce electrostatic forces between various parts of the MEMS device 400. The charge buildup can cause undesirable movement of the various movable MEMS components 403. If the charge buildup occurs near the first substrate 422, the charge buildup can exert an electrostatic force on the movable MEMS component 403 towards the inner surface of the first substrate 422. As a result, the movable MEMS component 403 is pulled towards the first substrate 422. Where the movable MEMS component 403 is configured to move laterally, the charge buildup can exert an electrostatic force on the movable MEMS component 403 in a direction out of the plane of the movable MEMS component's intended motion.

When the movable MEMS component 403 is pulled towards the first substrate 422, the movable MEMS component 403 may stick or adhere to the inner surface of the first substrate 422. For example, the movable MEMS component 403 may be stuck in an undesired open, closed or intermediate position. This phenomenon may be referred to as “fill stiction.” In some implementations, where the charge buildup is large enough, the electrostatic forces may pull the movable MEMS component 403 with enough force to bend or irreversibly damage the movable MEMS component 403. This can render the movable MEMS component 403 permanently damaged and inoperable.

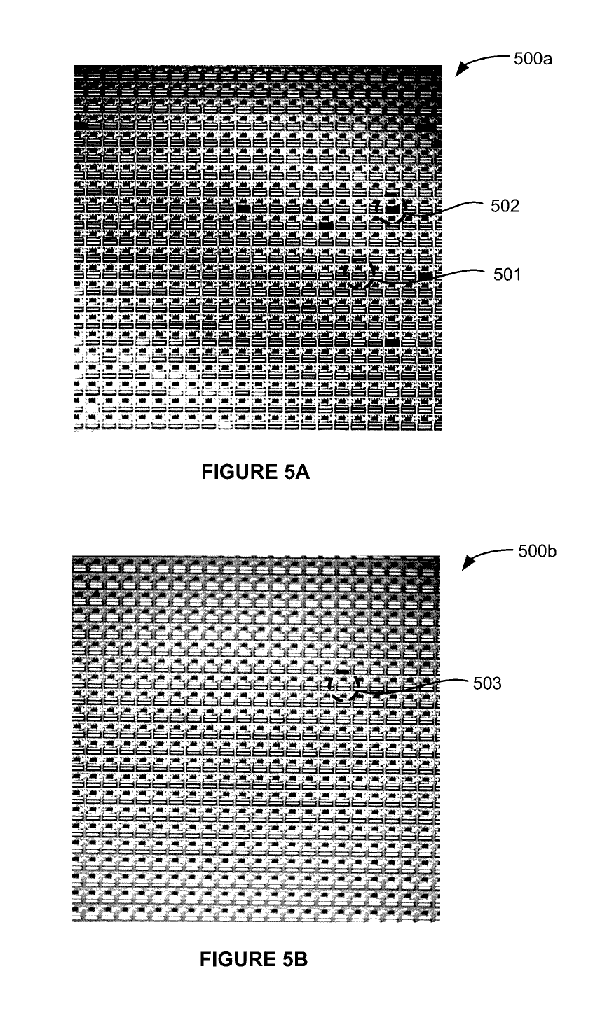

FIG. 5A shows an image of an array of MEMS elements in an example MEMS device illustrating the effects of stiction after the MEMS device is filled with fluid. The fluid can include silicone oil. A MEMS device 500a can include an array of MEMS elements 501, where the array of MEMS elements 501 can form a display. When the MEMS device 500a is filled with fluid, the fluid-filling process can be relatively violent so that a velocity of a fluid front creates friction between surfaces of the MEMS device 500a and the fluid. The friction generates a triboelectric force so that charge affinity between the surface of the MEMS elements 501 and another surface of the MEMS device 500a to develop. This can result in adhesion of one or more MEMS elements 501 to a surface of the MEMS device 500a, leading to “stuck” MEMS elements 502 in an undesired open, closed or intermediate state. The stuck MEMS elements 502 can lead to inoperable pixels in the display. As shown in FIG. 5A, such pixels may appear as black or darkened spots.

To reduce the effects of stiction during filling, some approaches may apply a thin film or SAM coating to the inner surfaces of the substrates in a MEMS device. The thin film or SAM coating may reduce the surface energy of the inner surfaces so that low surface energy coatings interact with the fluid. The low surface energy coatings can include passivation, organic coatings that can coat entire surfaces in the MEMS device to reduce the likelihood of stiction.

Returning to FIG. 4, if SAM coatings were deposited on one or both of the inner surfaces of the first substrate 422 and the second substrate 404, then the SAM coatings will reduce charge buildup resulting from the fluid 430 interacting with the first substrate 422 and/or the second substrate 404. Thus, lowering of the surface energy of one or both of the inner surfaces of the first substrate 422 and the second substrate 404 can alleviate the fill stiction problem. However, deposition of SAM coatings to the MEMS device 400 requires an additional coating process, which can require additional processing equipment and additional time and cost. Furthermore, the additional time may be substantial for MEMS-based displays, where the time for depositing a SAM coating can be several hours for a 5.1-inch display. In some implementations, even more time may be spent depositing the SAM coating around bonding lines (such as epoxy fill locations) after the bonding lines are formed, or depositing the SAM coating before the bonding lines are formed but removing the SAM coating where bonding lines are to be subsequently formed.

Instead of depositing thin film or SAM coatings to reduce the effects of fill stiction, a fluid may be doped with a surface energy modifier. The surface energy modifier can be mixed or otherwise incorporated with the fluid, where the surface energy modifier may be capable of reducing the surface energy of one or both inner surfaces of substrates in a MEMS device. The surface energy modifier may reduce the surface energy of one or both surfaces of substrates in the MEMS device simultaneous with the fluid-filling process. Accordingly, the surface energy modifier can reduce friction between the fluid and the inner surfaces of the MEMS device. The surface energy modifier can include a nonpolar functional group R. A functional group R can be a group of atoms that occur within an organic compound. A nonpolar functional group R can be the group of atoms that lack a dipole moment. For example, a nonpolar functional group R can have a symmetrical or substantially symmetrical arrangement of polar bonds. Examples of nonpolar functional groups are discussed in more detail below. In some implementations, incorporating the surface energy modifier in the fluid can reduce the effects of fill stiction while avoiding or alleviating costs associated with depositing thin film or SAM coatings.

FIG. 5B shows an image of an array of MEMS elements in an example MEMS device illustrating the effects of stiction reduction by a surface energy modifier after the MEMS device is filled with fluid. The fluid can include silicone oil with a surface energy modifier such as octadecyltrichlorosilane (OTMS), where a volume percent ratio of silicone oil to OTMS is 100:1. Nonetheless, it will be understood that the volume percent ratio of the silicone oil to OTMS can be any suitable amount to achieve stiction reduction, such as volume percent ratio of 20:1, 50:1, 100:1, or greater than 100:1. Similar to the MEMS device 500a in FIG. 5A, a MEMS device 500b can include an array of MEMS elements 503. When the fluid includes the surface energy modifier, such as OTMS, fewer MEMS elements 503 may be “stuck.” In fact, none of the MEMS elements 503 appear as black or darkened spots in the MEMS device 500b, thereby showing improvements in fill stiction reduction with the incorporation of a surface energy modifier.

Tables 1-3 show the effects of fill stiction comparing a fluid with only silicone oil, a fluid with OTMS, and a fluid with phenylethyltrimethoxysilane (PETMS). Some pixels in a 640×480 pixel display can be in an undesired open or closed state. An image can be taken of the pixel display before and after filling so that the number of pixels in the undesired open or closed state as a result of the fluid-filling process can be determined. A stiction percentage can be calculated by taking the difference before and after, and dividing that by the total number of pixels in the pixel display.

TABLE 1
Fluid with only silicone oil

| | Before Oil Fill | | After Oil Fill | | Stiction % | | |
|---|---|---|---|---|---|---|---|
| Sample | Closed | Open | Closed | Open | Closed | Open | Total % |
| 1 | 208 | 104 | 2664 | 1322 | 0.799 | 0.396 | 1.196% |
| 2 | 132 | 99 | 2330 | 1115 | 0.715 | 0.331 | 1.046% |
| 3 | 109 | 115 | 1277 | 194 | 0.380 | 0.026 | 0.406% |
| 4 | 110 | 132 | 764 | 287 | 0.213 | 0.050 | 0.263% |
| Average | | | | | | | 0.727% |

TABLE 2
Fluid with silicone oil and OTMS at 1 volume percent

| | Before Oil Fill | | After Oil Fill | | Stiction % | | |
|---|---|---|---|---|---|---|---|
| Sample | Closed | Open | Closed | Open | Closed | Open | Total % |
| 1 | 218 | 153 | 1005 | 259 | 0.256 | 0.035 | 0.291% |
| 2 | 107 | 149 | 399 | 247 | 0.095 | 0.032 | 0.127% |
| 3 | 124 | 56 | 792 | 96 | 0.217 | 0.013 | 0.230% |
| Average | | | | | | | 0.216% |

TABLE 3
Fluid with silicone oil and PETMS at 1 volume percent

| | Before Oil Fill | | After Oil Fill | | Stiction % | | |
|---|---|---|---|---|---|---|---|
| Sample | Closed | Open | Closed | Open | Closed | Open | Total % |
| 1 | 156 | 260 | 266 | 264 | 0.036 | 0.001 | 0.037 |
| 2 | 95 | 100 | 335 | 107 | 0.078 | 0.002 | 0.080% |
| 3 | 201 | 121 | 322 | 192 | 0.039 | 0.023 | 0.063% |
| Average | | | | | | | 0.06% |

Data from Table 1 shows that without a surface energy modifier, more than 0.7% of the pixels experience stiction as a result of the fluid-filling process. Data from Table 2 shows that by incorporating OTMS at 1 volume percent with silicone oil, about 0.2% of the pixels experience stiction as a result of the fluid-filling process. Furthermore, data from Table 3 shows that by incorporating PETMS at 1 volume percent with silicone oil, less than 0.1% of the pixels experience stiction as a result of the fluid-filling process. This demonstrates that inclusion of a surface energy modifier can substantially reduce the effects of fill stiction.

Fill stiction reduction can occur using a fluid doped with a surface energy modifier without detrimentally affecting the operating voltage and lifetime of the MEMS device. For an array of shutter-based light modulators, parameters such as dielectric constant, density, dynamic viscosity and switch time did not substantially change with the addition of OTMS or PETMS, as shown in Table 4. In addition, tests performed on display panels with only silicone oil, silicone oil with OTMS, and silicone oil with PETMS revealed that the pull-in voltage and best yield voltage did not substantially change with respect to one another for tests performed after 0 hours, 48 hours, 72 hours and 132 hours at 60° C. and 90% relative humidity. The pull-in voltage can refer to the voltage for fully opening and closing a shutter, and the best yield voltage can refer to the voltage for getting the most number of shutters functioning as possible.

TABLE 4

| | | | Dynamic | Simulated Switch |
|---|---|---|---|---|
| | Dielectric | Density | Viscosity | Time at 22 V |
| Fluid | Constant | (kg/m³) | (Pa-S) | (μs) |
| 0.65 Silicone | 2.28 | 760 | 4.95 × 10⁻⁴ | 143 |
| 0.65 Silicone | 2.29 | 762 | 4.96 × 10⁻⁴ | 142 |
| with 1 vol. % | | | | |
| PETMS | | | | |
| 0.65 Silicone | 2.29 | 763 | 4.97 × 10⁻⁴ | 142 |
| with 1 vol. % | | | | |
| OTMS | | | | |

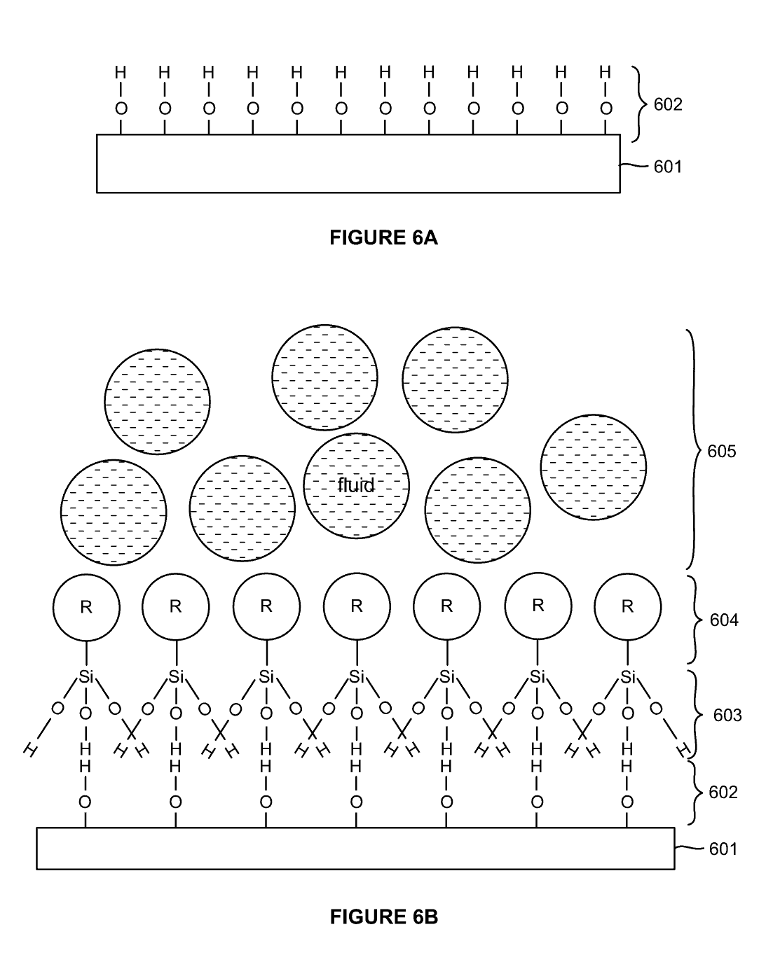

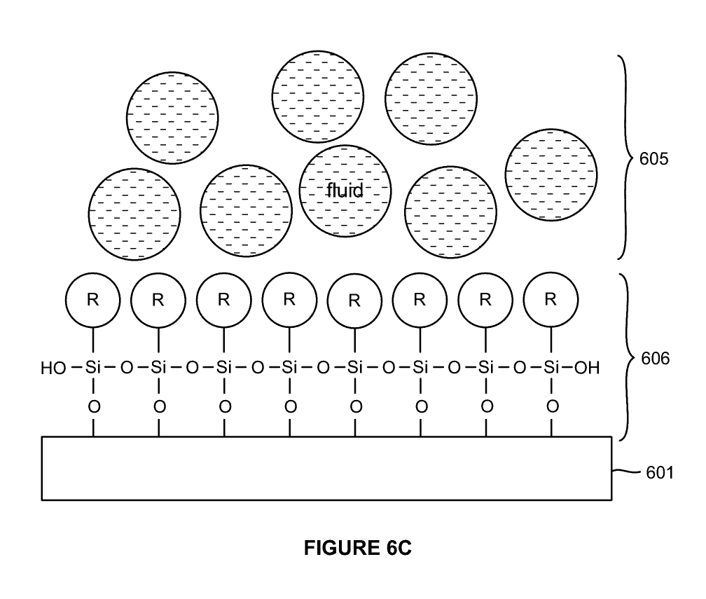

FIGS. 6A-6C show cross-sectional schematic views illustrating an example surface of a movable MEMS component and subsequent interactions with a fluid having a surface energy modifier. Without being limited by any theory, the cross-sectional schematic views can illustrate at a molecular level how the surface energy modifiers can modify the surface energy of the movable MEMS component. In particular, FIGS. 6A-6C illustrate the chemistry of modifying a MEMS surface from having high surface energy to low surface energy by using a surface energy modifier, where the MEMS surface interacts with a low surface energy fluid.

FIG. 6A shows a cross-sectional schematic view illustrating an example MEMS surface with surface hydroxyls. A MEMS surface 601 can include a surface of a movable MEMS component, where the MEMS surface 601 can include silicon, a nitride, an oxide and a metal. In some implementations, the MEMS surface 601 can include dangling bonds that can react with atmospheric water to produce surface hydroxyls 602. The surface hydroxyls 602 can interface with a fluid in the MEMS device, where the surface hydroxyls 602 can increase the surface energy of the MEMS surface 601.

A surface energy modifier can be incorporated in a fluid, where the fluid can include a low surface energy fluid such as an organic solvent. An example of such an organic solvent can include silicone oil. In some implementations, the surface energy modifier may be dissolved in the organic solvent. The surface energy modifier can be included in the fluid in relatively low concentrations, where the surface energy modifier can be between about 0.5 volume percent and about 5.0 volume percent of the fluid. In some implementations, the volume percent ratio of the fluid to the surface energy modifier can be 20:1, 50:1, 100:1, or greater than 100:1. In some implementations, the surface energy modifier can include a nonpolar functional group R, where the nonpolar functional group R is selected from the group consisting of: alkyl, aryl and naphthenic. An alkyl group has the general formula of CₙH₂ₙ₊₁. Examples include methyl, ethyl, propyl, isopropyl, butyl, s-butyl, isobutyl, neopentyl, hexyl, octyl, isohexyl, t-butyl groups, and the like. Alkyl groups can refer to the radical of saturated aliphatic groups, including straight-chain alkyl groups, branched-chain alkyl groups, cycloalkyl(alicyclic) groups, alkyl substituted cycloalkyl groups and cycloalkyl substituted alkyl groups. An aryl group is any functional group or substituent derived from an aromatic ring. Examples include phenyl, benzyl, napththyl, thienyl, indolyl, quinolyl, xylyl, tolyl, and the like. The aromatic ring can be substituted at one or more ring positions with substituents that are hydrophobic in nature. A naphthenic group refers to cycloalkane hydrocarbons having the general formula CₙH₂ₙ. Examples include derivatives of cyclopropane, cyclobutane, cyclopentane, cyclohexane, and the like. Suitable substituents for alkyl, aryl and naphthenic groups can include, for example, alkylcarbonyloxy, arylcarbonyloxy, alkoxycarbonyloxy, aryloxycarbonyloxy, aralkyl, or an aromatic or heteroaromatic moiety. Suitable substitutes also can include perfluorated alkyl, perfluorated aryl and perfluorated naphthenic groups, should the perfluoration be chemically feasible. In some implementations, the surface energy modifier can include a hydrolysable silane molecule, where the hydrolysable silane molecule includes a hydrolysable group R′ selected from the group consisting of: alkoxy, acyloxy, amine and chlorine. Hence, in some implementations, the surface energy modifier can include a silicon atom, the functional group R and the functional group R′. When the surface energy modifier is combined with the fluid, the surface energy modifier can be dissolved in ambient water and hydrolyzed into silanols. The hydrolysis of the surface energy modifier into silanols can be shown in the following chemical reaction:

R—(Si—R′)₃+3H₂O→R—(Si—OH)₃+3R′—OH.

Examples of surface energy modifiers can include but are not limited to PETMS, OTMS, phenyltrimethoxysilane (PTS), dodecyltrimethoxysilane (DDTMS), dodecyltriethoxysilane (DDTES), phenethylalcohol (PEA), octadecyltrichlorosilane (OTS), trichlorocyclohexylsilane and diisopropyldimethylaminooctylsilane. The chemical structure of such modifiers can include nonpolar functional groups, such as long hydrocarbon chains or long chains of perfluorocarbons. In some implementations, the surface energy modifier can be hydrolyzed according to the chemical reaction above to produce polar silanols bonded to a nonpolar functional group R. In some implementations, the surface energy modifier can include cyclic molecules that go through ring-opening reactions without water at low temperatures. The opened ring becomes a non-polar chain with silanols at one end. Examples include cyclic azasilanes such as n-butyl-aza-2,2-dimethoxysilacyclopentane and n-methyl-aza-2,2,4-trimethylsilacycloptentane. In some implementations, the modifier can include a long chain polyolefin with two or more hydrolysable functional groups R′ on both ends of the molecule, such as n-(2-aminoethyl)-3-aminopropyltrimethoxysilane.

FIG. 6B shows a cross-sectional schematic view illustrating an example MEMS surface with a modified surface interacting with a fluid. Surface hydroxyls 602 can provide a high surface energy to the MEMS surface 601. A surface energy modifier can include a hydrolysable silane molecule that can be broken up by ambient water to form polar silanols 603 having a nonpolar functional group R 604. The polar silanols 603 can interact with the surface hydroxyls 602 by a weak hydrogen bonding, and the nonpolar functional group R 604 can interface with a low surface energy fluid 605. In some implementations, the low surface energy fluid 605 can be an organic solvent, such as silicone oil. An interfacial layer between the low surface energy fluid 605 and the MEMS surface 601 can be formed, where the interfacial layer is capable of reducing the friction between the low surface energy fluid 605 and the MEMS surface 601. The interfacial layer can include the nonpolar functional group R 604, where the nonpolar functional group R 604 provides a low surface energy interface with the low surface energy fluid 605. The polar silanols 603 have one or more hydroxyl groups that can be attracted to the surface hydroxyls 602 via a weak force to hold the interfacial layer to the MEMS surface 601. This reaction to form the interfacial layer between the low surface energy fluid 605 and the MEMS surface 601 can happen spontaneously during the fluid-filling process.

FIG. 6C shows a cross-sectional schematic view illustrating a MEMS surface with a modified surface following an annealing process. An annealing process can heat the MEMS device to a temperature greater than about 100° C. to induce a condensation reaction that boils off water. Rather than a weak linkage between hydrogen atoms to hold the interfacial layer in place, the condensation reaction can remove water molecules to form a stronger covalent linkage between a silicon atom and an oxygen atom. An anchored interfacial layer 606 can be formed on the MEMS surface 601 following the condensation reaction. The anchored interfacial layer 606 provides a low surface energy surface to interface with the low surface energy fluid 605. In some implementations, the anchored interfacial layer 606 can serve as a lubrication layer for MEMS motions. The anchored interfacial layer 606 can reduce the effects of stiction after the fluid-filling process, including during normal operation of the MEMS device. In addition, the annealing process may occur normally during the course of fabricating the MEMS device, thereby providing a more stable layer that can increase the long-term stability of the MEMS device.

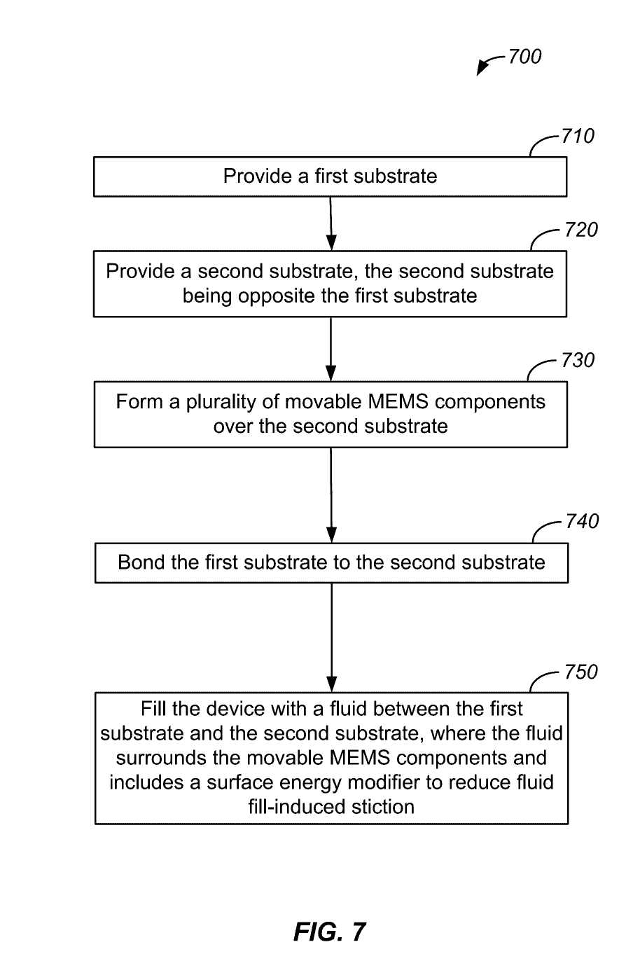

FIG. 7 shows a flow diagram illustrating an example process for manufacturing a device. The process 700 may be performed in a different order or with different, fewer or additional operations.

At block 710, a first substrate is provided. In some implementations, the first substrate can include a substantially transparent material, such as glass. Substantial transparency as used herein may be defined as transmittance of visible light of about 70% or more, such as about 80% or more or even about 90% or more. Glass substrates (sometimes referred to as glass plates or panels) may be or include a borosilicate glass, a soda lime glass, photoglass, quartz, Pyrex or other suitable glass material. In some implementations, the first substrate can be referred to as an aperture plate or a cover plate. Where the device is a display device, an image for a display can be provided through the first substrate.

At block 720, a second substrate is provided. In some implementations, the second substrate can include a substantially transparent material, such as glass. In some implementations, the second substrate can include a non-transparent or semi-transparent material, such as silicon. In some implementations, the second can be referred to as a back plate or a MEMS substrate. The second substrate may be provided opposite the first substrate.

At block 730, a plurality of movable MEMS components are formed over the second substrate. In some implementations, the movable MEMS components may be arranged in an array for a display device. The movable MEMS components can include moving mechanical parts that are capable of moving upon application of a bias. In some implementations, the movable MEMS components may include shutters, where the shutters may be part of shutter-based light modulators. Examples of shutter-based light modulators are discussed with reference to FIGS. 1A-4.

When the movable MEMS components are formed over the second substrate, the composition of the movable MEMS components may provide a surface having a high surface energy. For example, a surface of the movable MEMS components can include at least one of silicon, a nitride, an oxide and a metal. Thus, the surface of the movable MEMS components over the second substrate may have a higher surface energy than a surface of the first substrate facing the movable MEMS components.

At block 740, the first substrate is bonded to the second substrate. In some implementations, a sealing material can be provided around a periphery of the device. In some implementations, the sealing material can be provided on one or both of the first substrate and the second substrate. The sealing material can include but is not limited to an epoxy adhesive, a frit or a solder. The sealing material can contact both the first substrate and the second substrate, where the first substrate and the second substrate can be aligned prior to contact. The sealing material can be configured to form a hermetic, semi-hermetic or non-hermetic seal for the device. In some implementations, when an epoxy adhesive is dispensed, the epoxy adhesive can bond the first substrate to the second substrate after a thermal or ultraviolet (UV) cure. A gap can exist between the two substrates, where the gap can be maintained by the sealing material between the two substrates.

At block 750, the device is filled with fluid between the first substrate and the second substrate. The fluid surrounds the movable MEMS components and includes a surface energy modifier to reduce fluid fill-induced stiction. In some implementations, the surface energy modifier includes a nonpolar functional group R. In some implementations, the device may be immersed in fluid so that the fluid fills the gap between the two substrates. Air or other gas can be removed from the gap between the two substrates prior to immersion in the fluid. The device may be enclosed by the sealing material such that the fluid is enclosed within the sealing material. In some implementations, fill holes may be plugged with the sealing material after the device is filled with fluid.

In some implementations, the surface energy modifier is between about 0.5 volume percent and about 5.0 volume percent of the fluid. For example, the volume percent ratio of the fluid to the surface energy modifier can be 20:1, 50:1, 100:1, or greater than 100:1. The surface energy modifier in the fluid can prevent stiction between the movable MEMS components and the first substrate or the second substrate during the operation of filling the device with the fluid. The nonpolar functional group R can be selected from the group consisting of: alkyl, aryl and naphthenic. In some implementations, the method can further include annealing the device to a temperature greater than about 100° C. The annealing process can provide a stable interfacial layer of the surface of the movable MEMS components that reduces stiction during operation of the device.

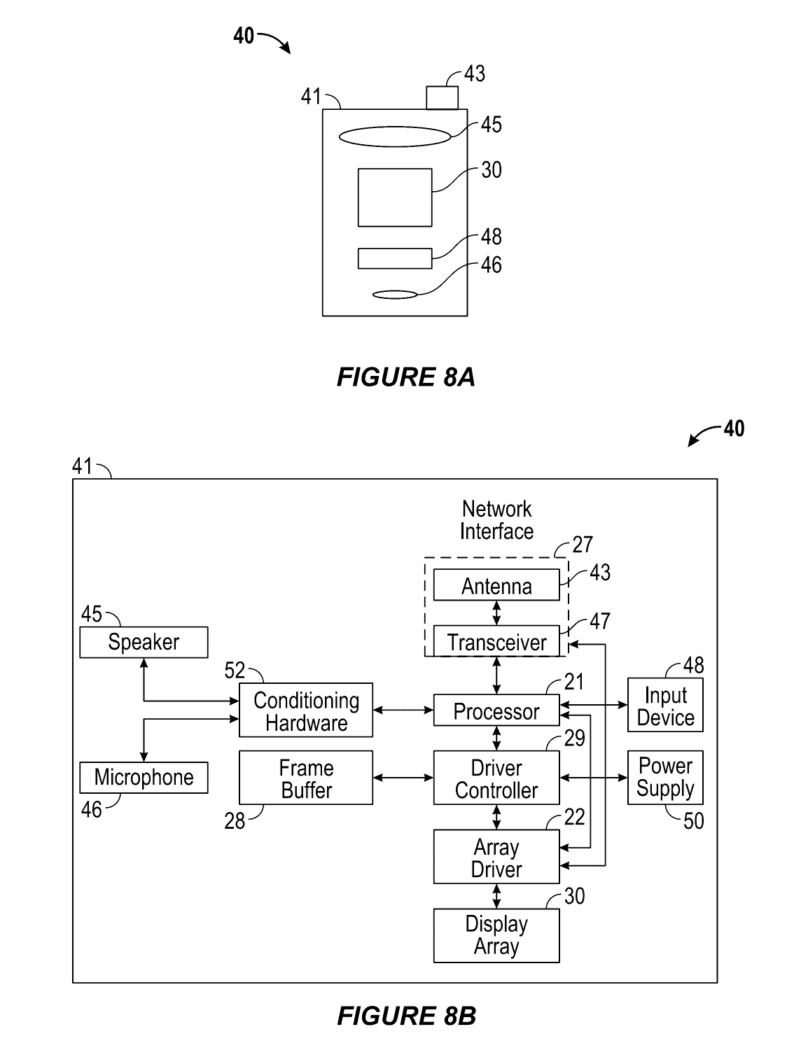

FIGS. 8A and 8B show system block diagrams of an example display device 40 that includes a plurality of display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be capable of including a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 30 can include a mechanical light modulator-based display, as described herein.

The components of the display device 40 are schematically illustrated in FIG. 8B. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 8A, can be capable of functioning as a memory device and be capable of communicating with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to any of the IEEE 16.11 standards, or any of the IEEE 802.11 standards. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G, or further implementations thereof, technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29 is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40. Additionally, in some implementations, voice commands can be used for controlling display parameters and settings.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower,” “front” and “behind,” “above” and “below” and “over” and “under,” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A device comprising:
a first substrate;
a second substrate opposite the first substrate;
a plurality of movable MEMS components over the second substrate;
a fluid between the first substrate and the second substrate and surrounding the movable MEMS components; and
a seal for bonding the first substrate and the second substrate and enclosing the fluid in the device, wherein the fluid includes a surface energy modifier, the surface energy modifier including a nonpolar functional group R.

2. The device of claim 1, wherein the nonpolar functional group R is selected from the group consisting of: alkyl, aryl and naphthenic.

3. The device of claim 1, wherein the surface energy modifier includes a silicon atom, the nonpolar functional group R and a hydrolysable group R′, wherein the hydrolysable group R′ is selected from the group consisting of: alkoxy, acyloxy, amine and chlorine.

4. The device of claim 1, wherein the surface energy modifier is selected from the group consisting of: phenylethyltrimethoxysilane (PETMS), octyltrimethoxysilane (OTMS), phenyltrimethoxysilane (PTS), dodecyltrimethoxysilane (DDTMS), dodecyltriethoxysilane (DDTES), phenethylalcohol (PEA), octadecyltrichlorosilane (OTS), trichlorocyclohexylsilane and diisopropyldimethylaminooctylsilane.

5. The device of claim 1, wherein the surface energy modifier is between about 0.5 volume percent and about 5.0 volume percent of the fluid.

6. The device of claim 1, wherein the first substrate includes an aperture plate and the second substrate includes a MEMS substrate, an inner surface of the MEMS substrate having a higher surface energy than an inner surface of the aperture plate.

7. The device of claim 6, wherein the surface energy modifier is capable of reducing the surface energy of the MEMS substrate.

8. The device of claim 1, wherein a surface of the movable MEMS components includes at least one of a silicon, a nitride, an oxide and a metal.

9. The device of claim 1, wherein the fluid includes an organic solvent.

10. The device of claim 9, wherein the surface energy modifier is dissolved in the organic solvent.

11. The device of claim 9, wherein the surface energy modifier forms an interfacial layer between the organic solvent and a surface of the movable MEMS components, the interfacial layer capable of reducing friction between the organic solvent and the surface of the movable MEMS components.

12. The device of claim 11, wherein the interfacial layer includes polar silanols facing the surface of the movable MEMS components and nonpolar functional group R facing the organic solvent.

13. The device of claim 1, wherein each of the movable MEMS components includes a shutter in a shutter-based MEMS light modulator.

14. The device of claim 1, further comprising:
a display;
a processor capable of communicating with the display, the processor being capable of processing image data; and
a memory device capable of communicating with the processor.

15. The device of claim 14, further comprising:
a driver circuit capable of sending at least one signal to the display; and
a controller capable of sending at least a portion of the image data to the driver circuit.

16. The device of claim 14, further comprising:
an image source module capable of sending the image data to the processor, wherein the image source module includes at least one of a receiver, transceiver and transmitter.

17. The device of claim 14, further comprising:
an input device capable of receiving input data and communicating the input data to the processor.

18. A device comprising:
a first substrate;
a second substrate opposite the first substrate;
a plurality of movable MEMS components over the second substrate, wherein a surface energy of a surface of the movable MEMS components is greater than a surface energy of the first substrate;
a fluid between the first substrate and the second substrate and surrounding the movable MEMS components, wherein the fluid includes:
a solvent; and
means for modifying a surface energy of the surface of the movable MEMS components, the surface energy modifying means including a nonpolar functional group R; and
a seal for bonding the first substrate and the second substrate and enclosing the fluid in the device.

19. The device of claim 18, wherein the nonpolar functional group R is selected from the group consisting of: alkyl, aryl and naphthenic.

20. The device of claim 18, wherein the surface energy modifying means includes a silicon atom, the nonpolar functional group R and a hydrolysable group R′, wherein the hydrolysable group R′ is selected from the group consisting of: alkoxy, acyloxy, amine and chlorine.

21. The device of claim 18, wherein the surface energy modifying means is selected from the group consisting of: phenylethyltrimethoxysilane (PETMS), octyltrimethoxysilane (OTMS), pehnyltrimethoxysilane (PTS), dodecyltrimethoxysilane (DDTMS), dodecyltriethoxysilane (DDTES), phenethylalcohol (PEA), octadecyltrichlorosilane (OTS), trichlorocyclohexylsilane and diisopropyldimethylaminooctylsilane.

22. The device of claim 18, wherein the surface energy modifying means is between about 0.5 volume percent and about 5.0 volume percent of the fluid.

23. A method of manufacturing a device, comprising:
providing a first substrate;
providing a second substrate, the second substrate being opposite the first substrate;
forming a plurality of movable MEMS components over the second substrate;
bonding the first substrate to the second substrate; and
filling the device with a fluid between the first substrate and the second substrate, wherein the fluid surrounds the movable MEMS components and includes a surface energy modifier, the surface energy modifier including a nonpolar functional group R.

24. The method of claim 23, wherein the nonpolar functional group R is selected from the group consisting of: alkyl, aryl, and naphthenic.

25. The method of claim 23, wherein the surface energy modifier is between about 0.5 volume percent and about 5.0 volume percent of the fluid.

26. The method of claim 23, wherein the surface energy modifier in the fluid prevents stiction between the movable MEMS components and the first substrate or the second substrate during filling.

27. The method of claim 23, further comprising:
annealing the device to a temperature greater than about 100° C.
